(19) United States
(12) Patent Application Publication
(10) Pub. No.: US 2009/0104748 A1
(43) Pub. Date: Apr. 23, 2009

(54) METHOD FOR FABRICATING SELF-ALIGNED RECESS GATE TRENCH

(76) Inventor: Shian-Jyh Lin, Taipei County (TW)

Correspondence Address: NORTH AMERICA INTELLECTUAL PROPERTY CORPORATION, P.O. BOX 506, MERRIFIELD, VA, 22116, US

(21) Appl. No.: 12/049,383

(22) Filed: Mar. 17, 2008

(30) Foreign Application Priority Data
Oct. 18, 2007 (TW) 096139023

(51) Int. Cl. H01L 21/20

(52) U.S. Cl. 438/386; 257/E21.008

(57) ABSTRACT

A method for forming a recess gate trench includes a plurality of trench capacitors formed into a substrate having thereon a pad layer. A portion of the trench top oxide layer of each trench capacitor is etched away to form a hole. The hole is filled with a silicon layer that is coplanar with the pad layer. Shallow trench isolation (STI) structure is formed. A portion of the STI structure is etched away. The pad layer is then stripped. A spacer is formed on a sidewall of the silicon layer. A gate trench is then etched into the substrate in a self-aligned fashion.

### BACKGROUND OF THE INVENTION

1. Field of the Invention

The present invention relates generally to a method for fabricating semiconductor devices such as Dynamic Random Access Memory (DRAM). More specifically, the present invention relates to a method for making recess gate trench of a Metal-Oxide-Semiconductor (MOS) transistor device.

2. Description of the Prior Art

Integrated circuit devices are continually being made smaller in order to increase speed, make the device more portable and to reduce the cost of manufacturing the device. However, certain designs have a minimum feature size, which cannot be reduced without compromising the integrity of electrical isolation between devices and consistent operation of the device.

For example, dynamic random access memory devices (DRAMs), which use vertical metal oxide semiconductor field effect transistors (MOSFETs) with deep trench storage capacitors, have a minimum features size of approximately 90 nm˜0.15 μm. Below that size, the internal electric fields exceed the upper limit for storage node leakage, which decreases retention time below an acceptable level. Therefore, there is a need for different methods and/or different structures to further reduce the size of integrated circuit devices.

With the continued reduction in device size, sub-micron scale MOS transistors have to overcome many technical challenges. As the MOS transistors become narrower, that is, their channel length decreases, problems such as junction leakage, source/drain breakdown voltage, and data retention time become more pronounced.

One solution to decrease the physical dimension of ULSI circuits is to form recessed gate or “trench-type” transistors, which have a gate electrode buried in a groove formed in a semiconductor substrate. This type of transistor reduces short channel effects by effectively lengthening the effective channel length by having the gate extend into the semiconductor substrate.

The recess-gate MOS transistor has a gate insulation layer formed on sidewalls and bottom surface of a recess gate trench etched into a substrate, a conductive filling the recess, contrary to a planar gate type transistor having a gate electrode formed on a planar surface of a substrate. However, the aforesaid recessed-gate technology still has many shortcomings that need to be improved.

### SUMMARY OF THE INVENTION

It is one object of this invention to provide an improved method of fabricating a self-aligned recess gate trench for recessed gate MOS transistor devices of trench-capacitor DRAM.

According to the claimed invention, a method for fabricating a self-aligned recess gate trench is provided. A semiconductor substrate having a main surface and a pad layer on the main surface is provided. A plurality of trench capacitors are formed in the pad layer and in the semiconductor substrate. Each trench capacitor has a trench top oxide (TTO) layer that is coplanar with the pad layer. A thickness of the TTO layer is etched away to form a cavity on each trench capacitor. The cavity is filled with a sacrificing material layer. The sacrificing material layer is coplanar with the pad layer. A shallow trench isolation (STI) region is formed in the semiconductor substrate, wherein a top surface of the STI region is coplanar with the pad layer; Using the pad layer and the sacrificing material layer as an etching mask, an upper portion of the STI region is selectively etched away. The pad layer stripped off such that the sacrificing material layer protrudes from the main surface. A sidewall spacer is formed on the sidewall of the sacrificing material layer. Using the sidewall spacer as an etching mask, a dry etching process is performed to etch the semiconductor substrate, thereby forming a recess gate trench in a self-aligned fashion.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIGS. 1-7 are schematic, cross-sectional diagrams illustrating a self-aligned method of fabricating a recess gate trench in accordance with the first preferred embodiment of this invention; and

FIGS. 8-11 are schematic, cross-sectional diagrams illustrating a self-aligned method of fabricating a recess gate trench in accordance with the second preferred embodiment of this invention.

### DETAILED DESCRIPTION

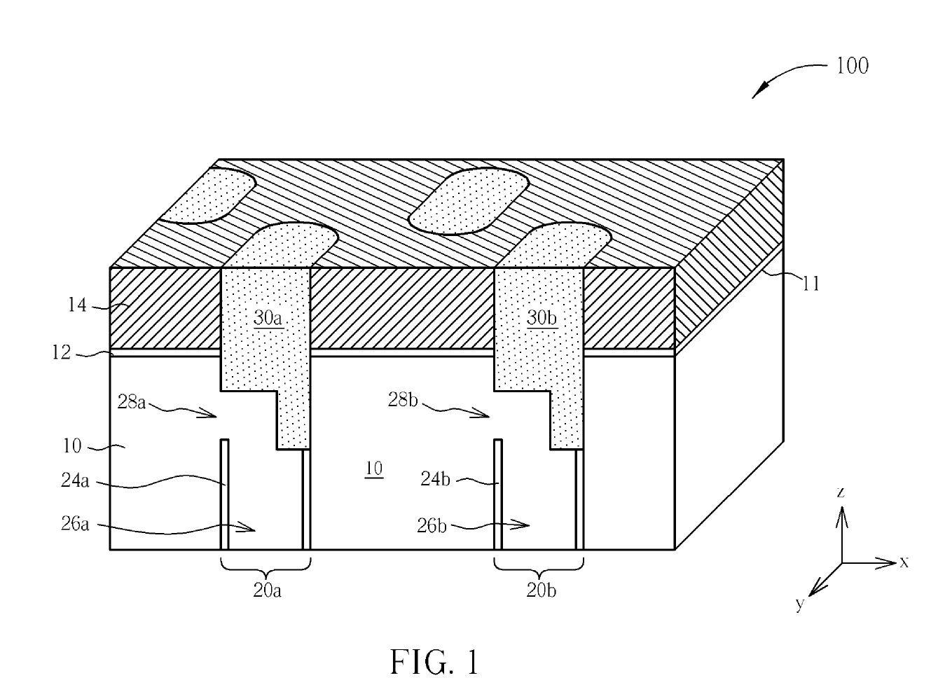

FIGS. 1-7 are schematic, cross-sectional diagrams illustrating a self-aligned method for fabricating a recess gate trench in accordance with the first preferred embodiment of this invention.

As shown in FIG. 1, a semiconductor substrate 10 is provided. A pad oxide layer 12 is deposited on the semiconductor substrate 10. A pad nitride layer 14 is deposited on the pad oxide layer 12. A plurality of deep trench capacitors 20a and 20b are formed within a memory array region 100 of the semiconductor substrate 10. The deep trench capacitors 20a and 20b are fabricated using methods known in the art. Therefore, the details of the fabrication method of forming the deep trench capacitors 20a and 20b are omitted.

The deep trench capacitor 20a includes a sidewall capacitor dielectric layer 24a and a doped polysilicon layer 26a, and the deep trench capacitor 20b includes a sidewall capacitor dielectric layer 24b and a doped polysilicon layer 26b. It is known that the doped polysilicon layers 26a and 26b functions as a top electrode of the deep trench capacitors 20a and 20b, respectively.

For the sake of simplicity, merely the upper portions of the deep trench capacitors 20a and 20b are schematically shown in the accompanying figures, while the lower portions of the deep trench capacitors 20a and 20b including the buried plate (capacitor bottom plate) are not shown.

A so-called Single-Sided Buried Strap (SSBS) process is carried out to form single-sided buried strap 28a and 28b in the upper portions of the deep trench capacitors 20a and 20b respectively. Subsequently, a Trench Top isolation Layer such as a Trench Top Oxide (TTO) layers 30a and 30b are formed to cap the single-sided buried strap 28a and 28b respectively. The TTO layers 30a and 30b, which may be made of silicon oxide deposited by high-density plasma chemical vapor deposition methods, extrude from a main surface 11 of the semiconductor substrate 10.

The aforesaid SSBS process generally comprises the steps of etching back the sidewall capacitor dielectric layers 24a and 24b and the doped polysilicon (or so-called Poly-2) 26a and 26b to a first depth; refilling the recess with another layer of polysilicon (or so-called Poly-3); etching back the Poly-3 to a second depth; forming an asymmetric spacer on interior sidewall of the recess; etching away the Poly-3 and Poly-2 that are not covered by the asymmetric spacer; filling the recess with TTO insulation layer; and chemical mechanical polishing the TTO insulation layer to form the TTO layers 30a and 30b that are substantially coplanar with the pad nitride layer 14.

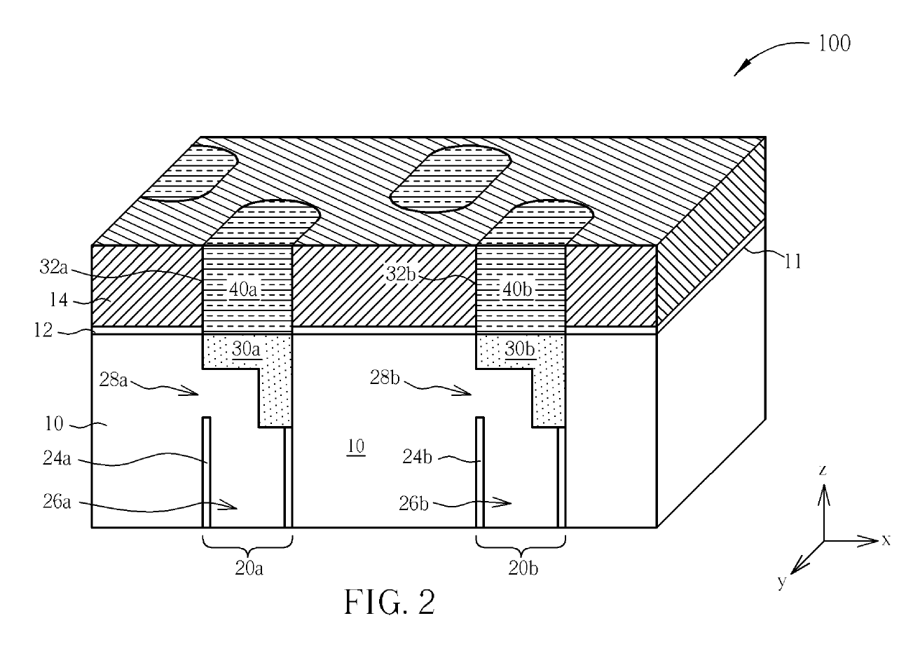

Subsequently, as shown in FIG. 2, an upper portion of the TTO layers 30a and 30b are selectively etched away. The pad nitride layer 14 is substantially intact. According to the preferred embodiment of this invention, the upper portions of the TTO layers 30a and 30b that are above the main surface 11 of the semiconductor substrate 10 are removed, thereby forming cavity 32a and cavity 32b directly above the deep trench capacitors 20a and 20b respectively.

Thereafter, a chemical vapor deposition (CVD) process is performed to deposit a polysilicon layer (sacrificing material layer; not shown) on the semiconductor substrate 10, which fills the cavities 32a and 32b. The excess polysilicon layer outside the cavities 32a and 32b and the polysilicon layer above the pad nitride layer 14 are removed by conventional chemical mechanical polishing (CMP) methods, thereby forming polysilicon plugs 40a and 40b within the cavities 32a and 32b respectively.

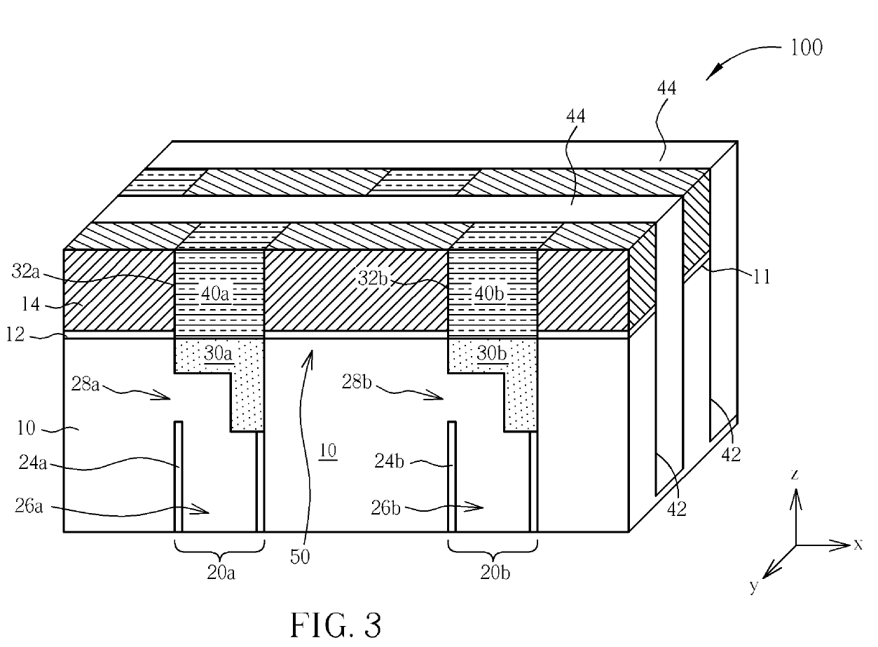

As shown in FIG. 3, a lithographic process and a subsequent dry etching process are carried out to define active areas and shallow trench isolation (STI) regions on the semiconductor substrate 10. To form the STI regions, the pad nitride layer 14, the pad oxide layer 12 and the semiconductor substrate 10 within the pre-determined strip areas is etched away, thereby forming line-shaped isolation trenches 42 elongating along the reference x-axis and the line-shaped active areas 50 between the deep trench capacitors 20a and 20b. Each of the line-shaped isolation trenches is parallel to each other.

It is understood that when etching the isolation trenches 42, portions of the deep trench capacitors 20a and 20b and portions of the polysilicon plugs 40a and 40b above the deep trench capacitors 20a and 20b are pared away. Thereafter, an insulating layer (not shown) such as HDPCVD oxide is deposited on the semiconductor substrate 10 and fills the isolation trenches 42.

The excess insulating layer outside the isolation trenches 42 and the insulating layer above the pad nitride layer 14 are removed by conventional CMP methods, thereby forming STI regions 44. At this point, the top surfaces of the STI regions 44 are coplanar with the top surfaces of the polysilicon plugs 40a and 40b and with top surfaces of the pad nitride layer 14.

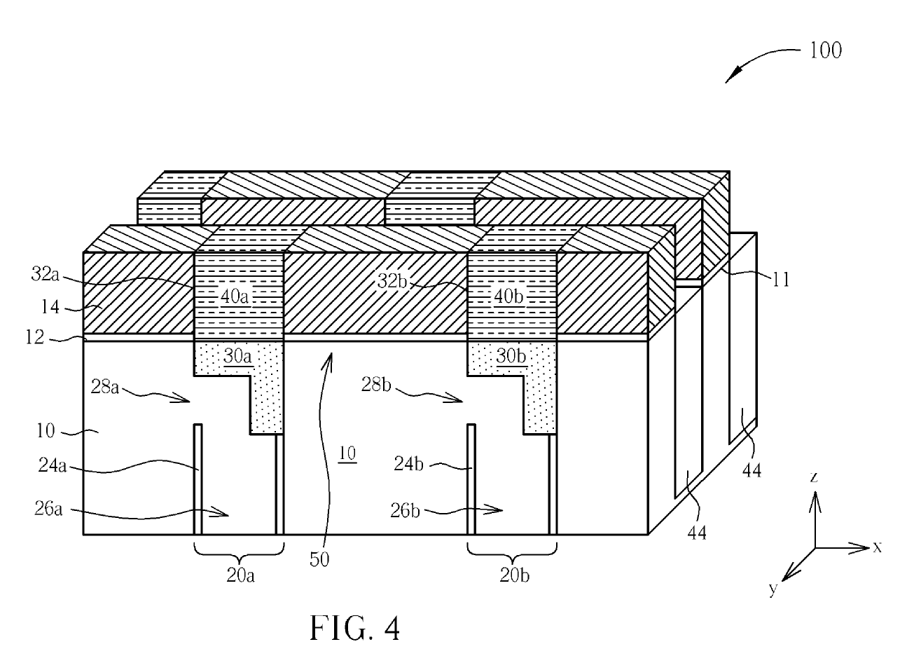

As shown in FIG. 4, using the polysilicon plugs 40a and 40b as well as the pad nitride layer 14 as an etching mask, an etching process is performed to selectively etch away an upper portion of the STI regions 44. According to the preferred embodiment of this invention, the thickness of the STI regions 44 that is above the main surface 11 of the semiconductor substrate 10 is removed.

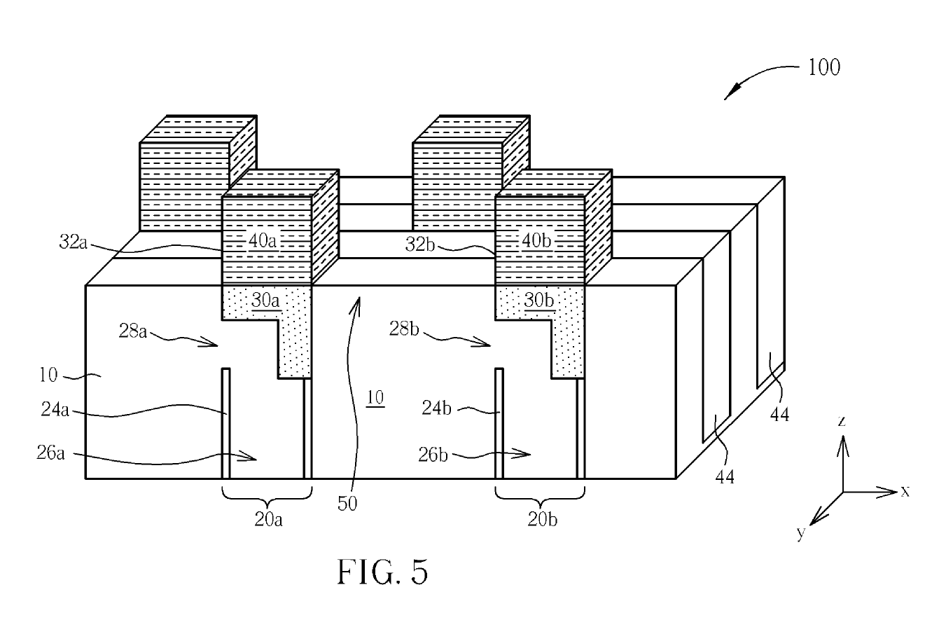

As shown in FIG. 5, another etching process is carried out to selectively etch away the pad nitride layer 14 and the pad oxide layer 12. At this point, merely the polysilicon plugs 40a and 40b directly above deep trench capacitors 20a and 20b protrude from the main surface 11 of the semiconductor substrate 10. The aforesaid etching process for etching the pad nitride layer 14 and the pad oxide layer 12 may include various wet etching methods including but not limited to hot phosphorous wet etching.

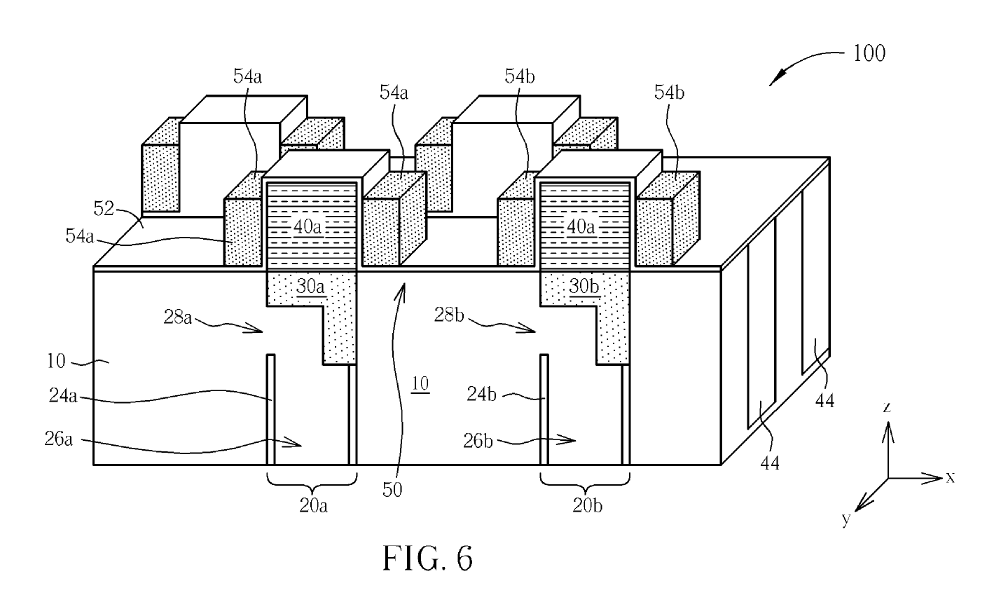

As shown in FIG. 6, a conformal silicon nitride lining layer 52 is deposited on the semiconductor substrate 10. The silicon nitride lining layer 52 conformally covers the top surface and sidewalls of the polysilicon plugs 40a and 40b. The silicon nitride lining layer 52 also covers the top surfaces of the STI regions and the active areas 50.

Thereafter, a pair of sidewall spacers 54a and a pair of sidewall spacers 54b are formed on opposite sidewalls of the polysilicon plugs 40a and 40b. As specifically indicated in FIG. 6, the pairs of sidewall spacers 54a and 54b are disposed along the reference x-axis. To form the sidewall spacers 54a and 54b, a silicon layer (not shown) such as amorphous silicon or polysilicon is deposited. The silicon layer is then anisotropically etched to form annular sidewall spacers around the polysilicon plugs 40a and 40b. An x-direction tilt-angle ion implantation process is then performed to implant dopants such as BF2 into the annular sidewall spacers along the reference x-axis. Thereafter, a selective etching process is carried out to remove the non-doped portions of the annular sidewall spacers along the reference y-axis.

Optionally, an oxidation process may be performed to oxidize the sidewall spacers 54a and 54b formed on respective sidewalls of the polysilicon plugs 40a and 40b. The sidewall spacers 54a and 54b cover a portion of the active areas 50. In a self-aligned fashion, the sidewall spacers 54a and 54b define the position and pattern of the recess gate trenches to be formed in the subsequent process steps, which are the active areas that are not covered by the sidewall spacers 54a and 54b.

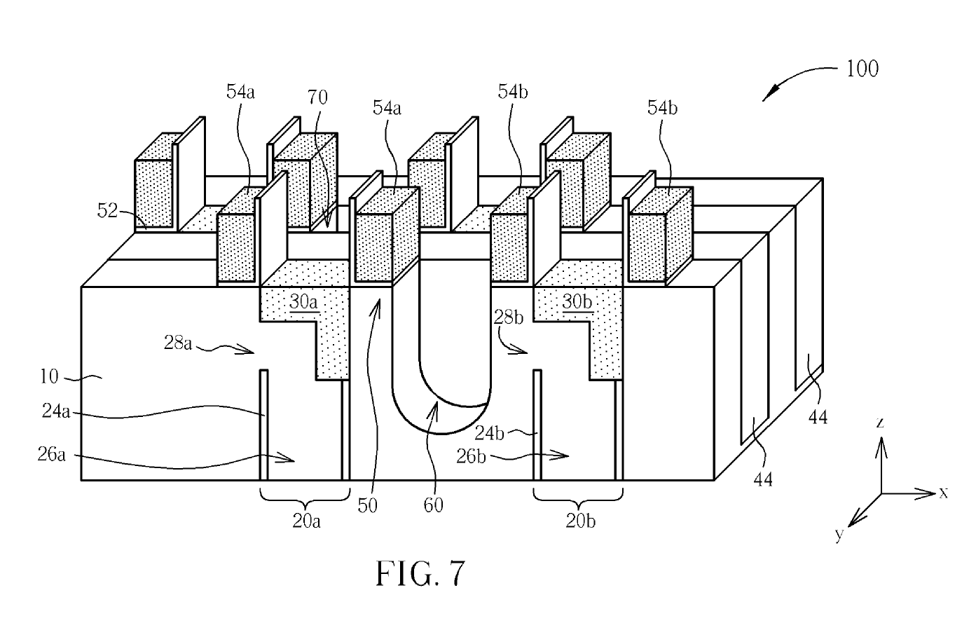

As shown in FIG. 7, using the sidewall spacers 54a and 54b as an etching mask, a self-aligned dry etching process is performed to etch the active areas 50 that are not covered by the sidewall spacers 54a and 54b, thereby forming recess gate trenches 60 into the semiconductor substrate 10. Preferably, the gate trenches 60 have a depth of 90-3000 angstroms, more preferably 2000 angstroms, below the main surface 11 of the semiconductor substrate 10. When etching the active areas 50 in order to form the recess gate trenches 60, the polysilicon plugs 40a and 40b are also removed, thereby forming recessed regions 70 directly above the deep trench capacitors 20a and 20b. Thereafter, the remaining silicon nitride lining layer 52 and the sidewall spacers 54a and 54b are removed.

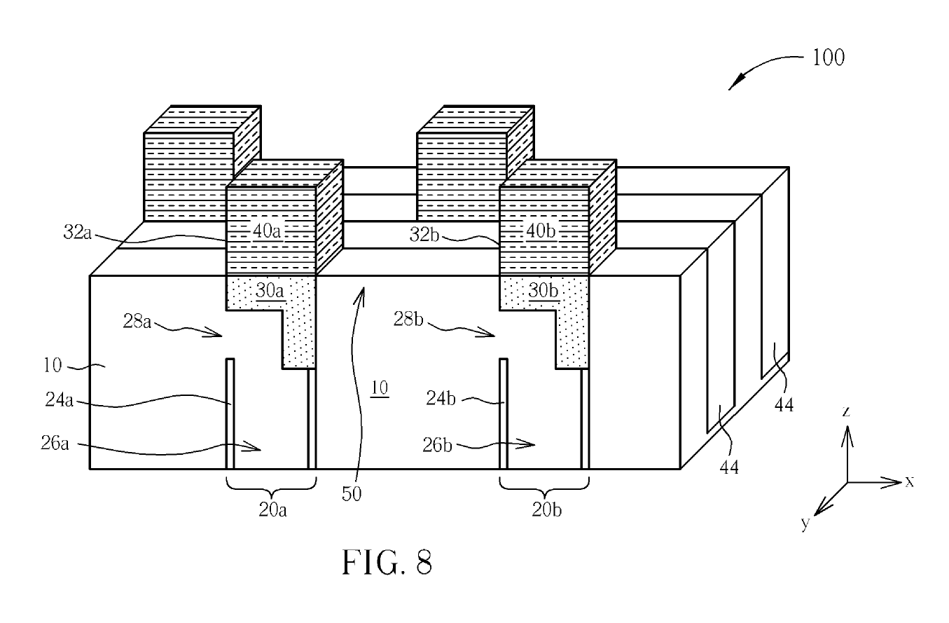

FIGS. 8-11 are schematic, cross-sectional diagrams illustrating a self-aligned method for fabricating a recess gate trench in accordance with the second preferred embodiment of this invention. It is noted that since the front-end process steps of the second preferred embodiment are the same as the steps set forth through FIG. 1 to FIG. 5, details of these front-end steps will not be repeated. For the sake of simplicity, the second preferred embodiment of this invention starts with the intermediate structure as depicted in FIG. 5.

As shown in FIG. 8, the pad nitride layer 14 is selectively removed. At this point, likewise, merely the polysilicon plugs 40a and 40b directly above deep trench capacitors 20a and 20b protrude from the main surface 11 of the semiconductor substrate 10. The aforesaid etching process for etching the pad nitride layer 14 and the pad oxide layer 12 may include various wet etching methods including but not limited to hot phosphorous wet etching.

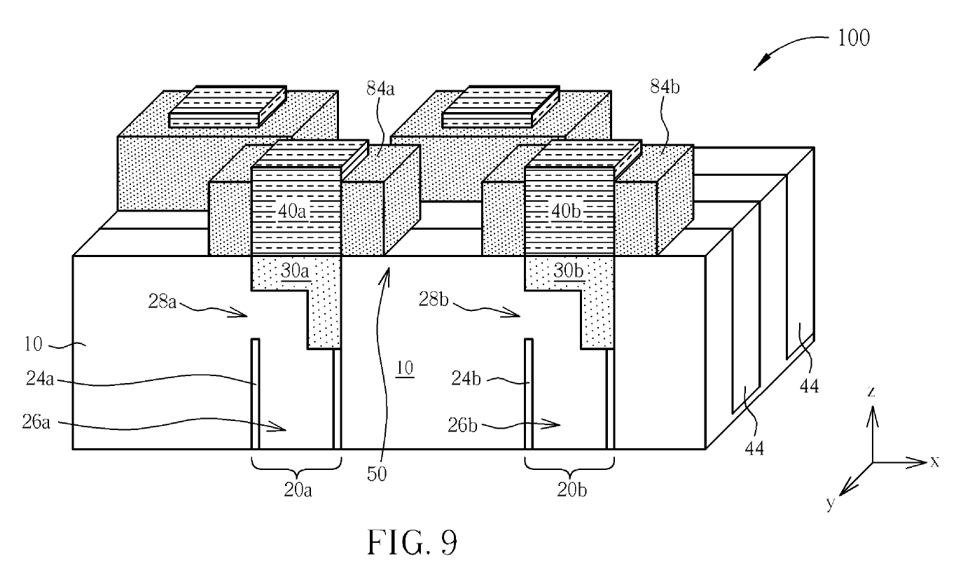

As shown in FIG. 9, annular sidewall spacers 84a and 84b are formed around the polysilicon plugs 40a and 40b. The annular sidewall spacers 84a and 84b directly border the sidewalls of the polysilicon plugs 40a and 40b without a lining layer therebetween. To form the annular sidewall spacers 84a and 84b, a silicon nitride layer (not shown) is deposited. A dry etching process is then performed to etch the silicon nitride layer until portions of the active areas 50 are exposed.

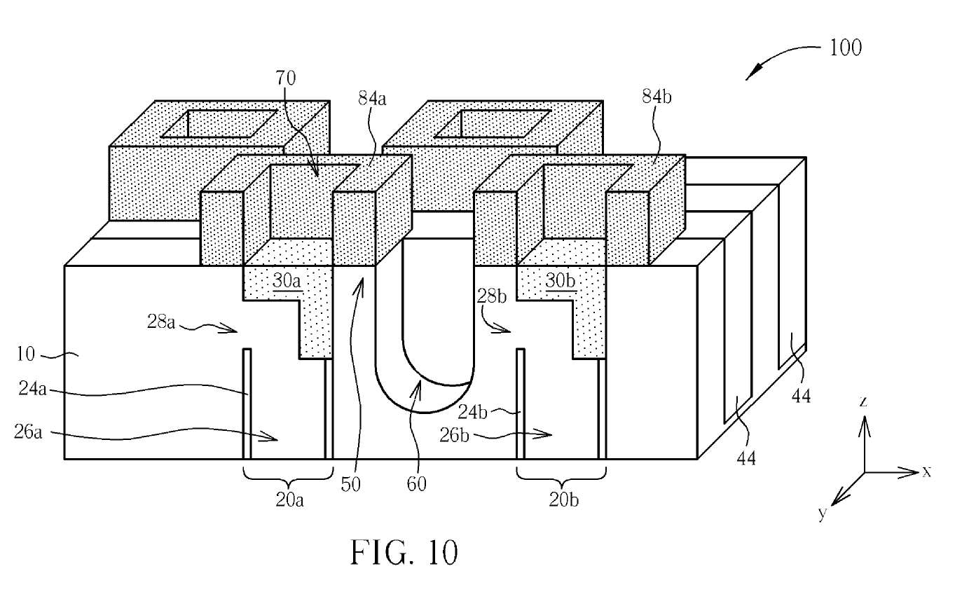

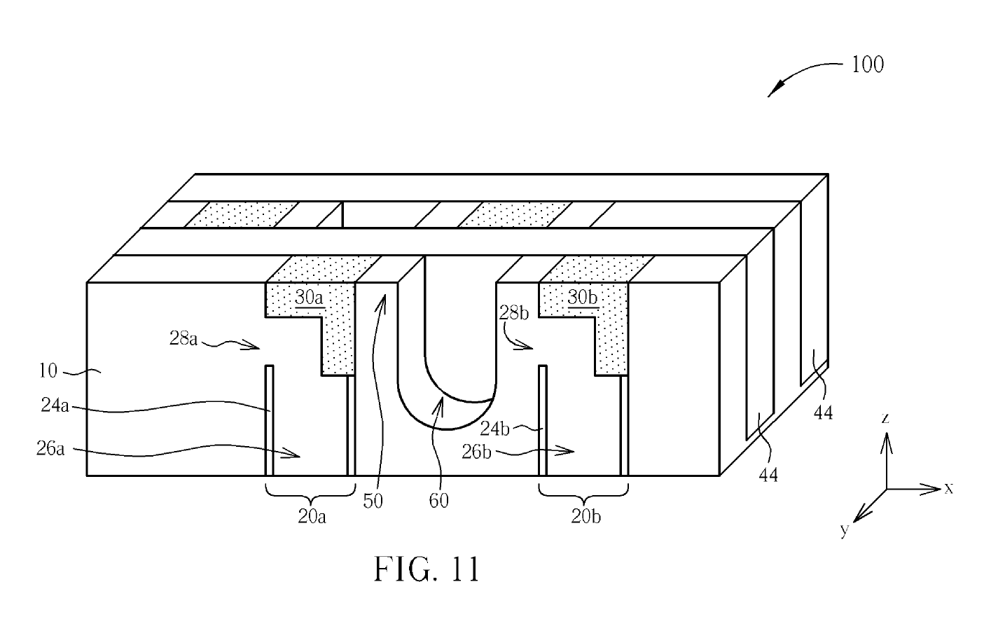

As shown in FIG. 10, using the sidewall spacers 84a and 84b as an etching mask, a self-aligned etching process is carried out to selectively etch the active areas 50 that are covered by the sidewall spacers 84a and 84b, thereby forming recess gate trenches 60 in the semiconductor substrate 10. Preferably, the gate trenches 60 have a depth of 90-3000 angstroms, more preferably 2000 angstroms, below the main surface 11 of the semiconductor substrate 10. When etching the active areas 50 in order to form the recess gate trenches 60, the polysilicon plugs 40a and 40b are also removed, thereby forming recessed regions 70 directly above the deep trench capacitors 20a and 20b. As shown in FIG. 11, the sidewall spacers 84a and 84b are removed.

Those skilled in the art will readily observe that numerous modifications and alterations of the device and method may be made while retaining the teachings of the invention.

What is claimed is:

1. A method for fabricating a self-aligned recess gate trench, comprising:
providing a semiconductor substrate having a main surface and a pad layer formed on said main surface;
forming a plurality of trench capacitors in said pad layer and the plurality of trench capacitors extending into said semiconductor substrate, wherein each of said trench capacitors has an insulating layer on top of said trench capacitors and having a top face being coplanar with a top face of said pad layer;
forming a plurality of paralleled trench isolation regions in the semiconductor substrate, wherein a top surface of each of said trench isolation regions is coplanar with a top surface of said semiconductor substrate, such that the plurality of paralleled trench isolation regions are alternatingly formed relative to said trench capacitors;
removing said pad layer such that each of said insulating layers has a height higher than that of said semiconductor substrate;
forming a sidewall spacer surrounding each of said insulating layers; and
forming a plurality of trenches in said semiconductor substrate by using said sidewall spacers as an etching mask.

2. The method for fabricating a self-aligned recess gate trench according to claim 1, wherein after said pad layer removing step further comprises the step of:
conformally forming a lining layer on said semiconductor substrate to cover said insulating layers and said trench isolation regions.

3. The method for fabricating a self-aligned recess gate trench according to claim 1 further comprising a step of oxidizing said sidewall spacers.
